(19) United States
(12) Patent Application Publication
(10) Pub. No.: US 2025/0114821 A1
(43) Pub. Date: Apr. 10, 2025

(54) PMUT WITH CONTROLLED RESIDUAL STRESS AND PATTERNING

(71) Applicant: Invensense, Inc., San Jose, CA (US)

(72) Inventors: Stefon Eric Shelton, Oakland, CA (US); Benjamin Eric Eovino, Oakland, CA (US); Fabian Thomas Goericke, Berkeley, CA (US)

(21) Appl. No.: 18/811,706

(22) Filed: Aug. 21, 2024

Related U.S. Application Data
(60) Provisional application No. 63/587,752, filed on Oct. 4, 2023.

(51) Int. Cl. B06B 1/06; G06F 30/17

(52) U.S. Cl. CPC B06B 1/0603; G06F 30/17

(57) ABSTRACT

A piezoelectric micromachined ultrasonic transducer (“PMUT”) sensor has a target residual stress at one or more layers of the PMUT and also has patterning where some of the layers of the PMUT are removed. The residual stress and the patterning result in a static deflection of the PMUT. The application of the residual stress and the patterning define a vibration modeshape with desired acoustic characteristics such as improved signal-to-noise ratio (“SNR”).

### CROSS-REFERENCE TO RELATED APPLICATION

This application claims priority to U.S. Provisional Patent Application No. 63/587,752, filed Oct. 4, 2023, and entitled “PMUT Mode Shape Optimization,” which is incorporated by reference herein in its entirety for all purposes.

### BACKGROUND

Ultrasonic sensors such as a piezoelectric micromachined ultrasonic transducer (“PMUT”) sensor transmit an ultrasound signal or wave into an environment of interest and measure reflected signals that are received over time, with the timing and magnitude of the reflected or echo signal corresponding to the distance to an object of interest and the characteristics of the object causing the reflection. Accordingly, PMUT sensor are used for a variety of applications such as fingerprint sensors and object detection systems, which in turn are integrated into numerous end use devices such as security systems, door locks, computers, smart phones, tablet devices, vehicles, and the like.

A PMUT device includes a membrane that generates an acoustic output signal based on an electrical signal applied across a piezoelectric material layer, for example, by electrodes located on each side of the piezoelectric material layer. Similarly, an acoustic signal received at the piezoelectric material layer of the membrane is converted by the piezoelectric material layer to an electrical signal which is received and processed via the adjacent electrode layers. The design characteristics of the membrane such as shape, layer thicknesses, and additional support layers relate to the efficiency of the transmission and reception of acoustic signals. Changes to design characteristics impact key performance criteria such as electromechanical transduction efficiency, linearity, and signal-to-noise ratio (“SNR”) in a complex manner.

### SUMMARY

In some embodiments, a piezoelectric micromachined ultrasonic transducer (PMUT) comprises a membrane, which comprises a plurality of layers including at least a first electrode layer, a second electrode layer, and a piezoelectric layer located between the first electrode layer and the second electrode layer, wherein a first layer of the plurality of layers has a target residual stress. The PMUT further comprises a pattern on the membrane including removed portions of one or more of the plurality of layers, wherein a predetermined shape of a static deflection of the membrane is determined by the target residual stress of the first layer and the patterning of the membrane.

In some embodiments, a PMUT comprises a membrane, which comprises a plurality of layers including at least a first electrode layer, a second electrode layer, and a piezoelectric layer located between the first electrode layer and the second electrode layer, wherein a first layer of the plurality of layers has a target residual stress. The PMUT further comprises a pattern on the membrane including removed portions of one or more of the plurality of layers, wherein a predetermined vibration modeshape of the membrane is determined by the target residual stress of the first layer and the patterning of the membrane.

In some embodiments, a method for designing a PMUT comprises determining an initial PMUT design, including a shape of a membrane and a plurality of layers of the membrane, wherein the plurality of layers comprise at least a first electrode layer, a second electrode layer, and a piezoelectric layer located between the first electrode layer and the second electrode layer. The method further comprises applying a plurality of residual stresses to a first layer of the plurality of layers and applying a plurality of patternings to the membrane, wherein each patterning comprises a removal of portions of one or more of the plurality of layers. The method further comprises determining a static deflection associated with each combination of the target residual stresses and applied patternings and selecting one of the target residual stresses and one of the applied patternings based on the determined static deflections.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative PMUT system in accordance with an embodiment of the present disclosure;

FIG. 2A depicts an exemplary PMUT in accordance with an embodiment of the present disclosure;

FIG. 2B depicts the exemplary PMUT of FIG. 2A with example static deflection in accordance with an embodiment of the present disclosure;

FIG. 3A depicts another exemplary PMUT in accordance with an embodiment of the present disclosure;

FIG. 3B depicts the exemplary PMUT of FIG. 3A with example static deflection in accordance with an embodiment of the present disclosure;

FIG. 4 depicts exemplary plots of static deflection and normalized vibration modeshape for a plurality of residual stress conditions in accordance with an embodiment of the present disclosure;

FIG. 5 depicts exemplary plots of normalized vibration modeshape for a plurality of patterning radii in accordance with an embodiment of the present disclosure;

FIG. 6 depicts exemplary plots of static deflection and normalized vibration modeshape for a plurality of patterns and target residual stress conditions in accordance with an embodiment of the present disclosure; and

FIG. 7 depicts exemplary steps of selecting residual stresses and patterning a PMUT in accordance with an embodiment of the present disclosure.

### DETAILED DESCRIPTION

A PMUT sensor includes a plurality of layers such as electrode layers and a piezoelectric layer. During PMUT design, various parameters and design constraints are considered to design an appropriate sensor for a particular application. For example, different applications require different transmit power, receive sensitivity, transmit frequency, signal-to-noise ratio, etc. Numerous potential PMUT designs are available based on different shapes, layer materials, number and type of layers, layer thicknesses, bonding techniques, etc. In some designs, entire layers are removed in regions of the PMUT (e.g., in one or more contiguous or non-contiguous regions), resulting in physically separated active regions. Each of these design parameters impacts the performance of the PMUT in various ways.

The static deflection of a PMUT corresponds to a curvature or flexing of the PMUT device that results in a vertical displacement of portions of the PMUT device relative to a flat or zero plane. This static deflection is based in part on the design parameters as described above. Two particular design parameters that have a substantial, observable, and controllable impact on static deflection are a residual stress within PMUT layers and patterning of the PMUT to remove layers in certain areas. A residual stress can be selectively provided at layers, such as by modifying the manner of depositing or otherwise fabricating the layer and related conditions (e.g., temperature, pressure, concentration, etc.), the type of bonding between adjacent layers and/or specialized bonding, passivation, or isolation layers, and other similar factors. Patterning can be modified by changing the steps of material deposition and/or removal during fabrication to change characteristics of the patterning such as the size of the removed regions, shape of removed regions, the number of layers removed, contiguous or non-contiguous regions, other similar factors, and combinations thereof. Accordingly, through applying a residual stress to one or more layers and selectively patterning the PMUT, the static deflection of the PMUT can be controlled.

A PMUT's vibration modeshape is the spatial pattern of displacement or deformation that the PMUT membrane undergoes when excited electrically (e.g., during transmitting) or by an acoustic signal (e.g., during receiving). Among other factors, the vibration modeshape depends on the mechanical design and geometry of the PMUT as well as the PMUT layer materials. Different vibration modeshapes and modes (e.g., fundamental mode, harmonic modes, radial and tangential modes, asymmetric modes, etc.), in turn, are suitable for different applications, based on factors such as the specified bandwidth, transmit frequency sensitivity, receive frequency sensitivity, energy efficiency, beam shaping, SNR, electromechanical transduction efficiency, and linearity (e.g., of motion during PMUT vibration). A factor of the PMUT geometry that has a substantial, observable, and controllable impact on vibration modeshape is the static deflection. A desired vibration modeshape can be achieved by controlling the target residual stress and patterning of the PMUT to modify the static deflection of the PMUT.

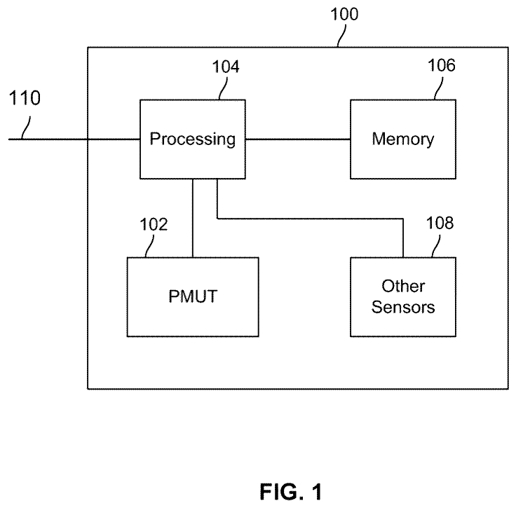

FIG. 1 shows an illustrative PMUT system 100 in accordance with an embodiment of the present disclosure. Although particular components are depicted in FIG. 1, it will be understood that other suitable combinations of the PMUTs, other sensors (e.g., microelectromechanical system (“MEMS”) or PMUT sensors) processing components, memory, and other circuitry may be utilized as necessary for different applications and systems. In accordance with the present disclosure, the PMUT system may include a PMUT sensor 102 as well as additional sensors 108. Although the present disclosure will be described in the context of signals received from certain PMUT sensor designs and configurations, it will be understood that the utilization of residual stress within PMUT layers (e.g., including differences in residual stress of adjacent or close layers) and selective patterning (e.g., material remove) to improve PMUT operation (e.g., vibration modeshape, signal-to-noise ratio, linearity) in accordance with the present disclosure may be utilized with a variety of PMUT designs, including a variety of different membrane materials, membrane layers, membrane shapes, fabrication techniques, and combinations thereof.

Processing circuitry 104 may include one or more components providing processing based on the requirements of the PMUT system 100. In some embodiments, processing circuitry 104 may include hardware control logic that may be integrated within a chip of a sensor (e.g., of a die of a PMUT sensor 102 or other sensors 108, or on an adjacent portion of a chip to the PMUT sensor 102 or other sensors 108) to control the operation of the PMUT sensor 102 or other sensors 108 and perform aspects of processing for the PMUT sensor 102 or the other sensors 108. In some embodiments, the PMUT sensor 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the PMUT sensor 102 by interacting with the hardware control logic and processing signals received from PMUT sensor 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the PMUT sensor 102 or other sensors 108 may communicate directly with external circuitry (e.g., via a serial bus or direct connection to sensor outputs and control inputs), in an embodiment the processing circuitry 104 may process data received from the PMUT sensor 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the PMUT sensor 102 and other sensors 108 into appropriate measurement units (e.g., based on settings provided by other computing units communicating over the communication interface 110).

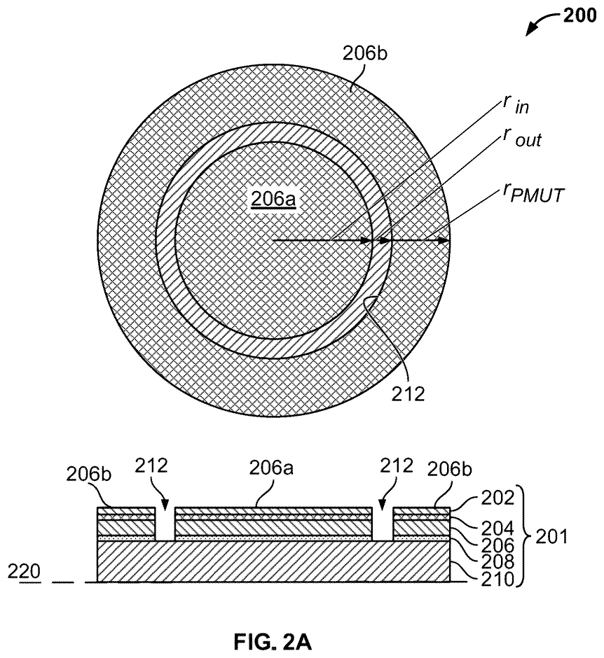

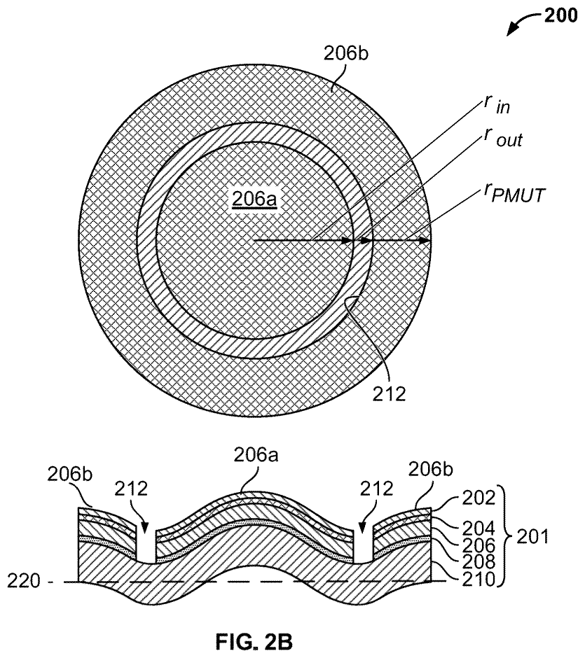

FIG. 2A depicts an exemplary PMUT 200 in accordance with an embodiment of the present disclosure. In the context of the present disclosure, PMUT structures will be depicted and described in simplified format, for example, with the PMUT device 200 having a membrane 201, with the membrane 201 including a piezoelectric layer 206 located between an upper electrode layer 204 and a lower electrode layer 208, an upper structural or passivation layer 202 located above the upper electrode layer (e.g., in the direction of transmission/reception), and a lower structural layer 210 located below and providing support for the other layers of the PMUT device. It will be understood that additional layers, intervening layers, bonding layers, and the like may be included within the membrane 201 layers in different embodiments, but are not specifically depicted in the figures herein. Exemplary materials for the layers of the membrane 201 may be aluminum nitride for the upper structural layer 202, molybdenum for the top electrode layer 204 and bottom electrode layer 208, aluminum nitride for the piezoelectric layer 206, and polysilicon for the lower structural layer 210, although it will be recognized that a variety of substitute materials may be used in different PMUT implementations. Further, although particular PMUT designs are depicted and described herein with respect to each of the figures, it will be understood that the PMUT optimization techniques utilized herein are equally applicable to other PMUT designs and shapes, including squares, rectangles, ovals, polygon, and irregular shapes, along with varieties of shapes and patterns of removed regions.

The membrane 201 includes a removed region 212 that in the embodiment of FIG. 2A is an annular ring within the circular PMUT 200 structure, and that defines respective non-removed regions 206a and 206b. In the embodiment depicted in FIG. 2A and in embodiments described herein, the removed region 212 may have all membrane 201 layers except for lower structural layer 210 removed, e.g., upper structural layer 202, upper electrode layer 204, piezoelectric layer 206, and lower electrode layer 208. With these layers removed, the removed region 212 is inactive, e.g., does not actively participate in the generating or receiving of acoustic signals to directly create or respond to electrical signals, although as described herein inactive layers do participate in dictating the static deflection of the PMUT 200 and corresponding vibration modeshape. Although for purposes of illustration figures herein may be depicted and described with a single removed region, it will be understood that multiple removed regions may be included and may have different shapes, sizes, and removed layers in different implementations.

The removed region 212 has an inner radius rin and an outer radius rout, while the circular PMUT 200 as a whole has an outer radius rpMUT. In the context of the exemplary PMUT 200 of FIG. 2A, these values collectively define the location and area of each of the non-removed regions 206a and 206b as well as the removed region 212. As is described herein, modifications to the location, shape, area, removed layers, and other characteristics of the removed regions (e.g., removed region 212) changes the static deflection of the membrane 201. For example, without any static deflection, the membrane 201 and each of its layers lies completely flat when viewed from the side or as a cross section. However, in actual implementations there is often a static deflection of the PMUT with respect to an undeflected plane 220. The static deflection is impacted by a number of factors, including the design of the PMUT 200 (e.g., circular in FIG. 2A, or rectangular, square, triangular, hexagonal, irregular shaped, other shapes, and combinations thereof in other embodiments), locations and size of removed regions (e.g., removed regions 212), and other factors such as a residual stress within one or more PMUT layers, including based on differences in residual stress of adjacent or closely located layers.

When the layers are deposited or otherwise fabricated with respect to each other, each layer and/or layer-to-layer bonding area may have a residual stress, for example, based on the material of the layers, the manner of depositing or otherwise fabricating the layer and related conditions (e.g., temperature, pressure, power, concentration, etc.), the type of bonding between adjacent layers and/or specialized bonding, passivation, or isolation layers, and other similar factors. In some instances, these factors can be controlled to achieve a desired (e.g., target) residual stress within a particular layer or layers and/or layer-to-layer bonding area or areas in a predetermined manner. For example, aspects of the deposition process or bonding techniques for a PMUT layer, electrode layers, upper structural layers, bonding layers, passivation layers, isolation layers, or other layers may be controlled to achieve a known residual stress within particular layers and/or the PMUT structure as a whole. This residual stress in turn impacts static deflection and thus vibration modeshape, with a larger magnitude of residual stress (compressive or tensile) within individual layers generally corresponding to an overall increase in the static deflection and associated changes in vibration modeshape. Moreover, if desired, a target residual stress may only be added to a portion of a layer to achieve additional variations in static deflection and vibration modeshape.

FIG. 2B depicts the exemplary PMUT of FIG. 2A with example static deflection in accordance with an embodiment of the present disclosure. The PMUT 200 depicted in FIG. 2A is identical to FIG. 2B, except that in the cross sectional view of FIG. 2B the static deflection of PMUT 200 is depicted with respect to the undeflected plane 220 of the membrane 201. Although a particular static deflection pattern will differ for different PMUT 200 shapes, removed regions, and the like, in the embodiment depicted in FIG. 2B the portions of the membrane 201 corresponding to the removed regions 212 and the non-removed region 206b generally deflect below the undeflected plane 220, for example, based on the combination of layer stresses and patterning of membrane 201. Additionally, in response to a target residual stress that increases the residual stress within one or more of the layers or portions thereof, the magnitude, curvature, and slope of the particular deflection will be increased. For example, if the residual stress magnitude were to be increased across the entirety of piezoelectric layer 206, the deflection of the non-removed region 206a above the undeflected plane 220 may increase, and the deflection associated with the non-removed region 206b and removed region 212 may also increase further below the undeflected plane 220. As will be described herein, different patterns of static deflection caused by changes in patterning of removed regions and target residual stress in turn result in changes to the vibration modeshape, allowing the vibration modeshape to be effectively “tuned” for performance characteristics such as improved electromechanical transduction efficiency, improved SNR, and improved linear performance, and allows achievement of a modeshape with desirable characteristics such as a maximizing the curvature within piezoelectric active regions of the membrane.

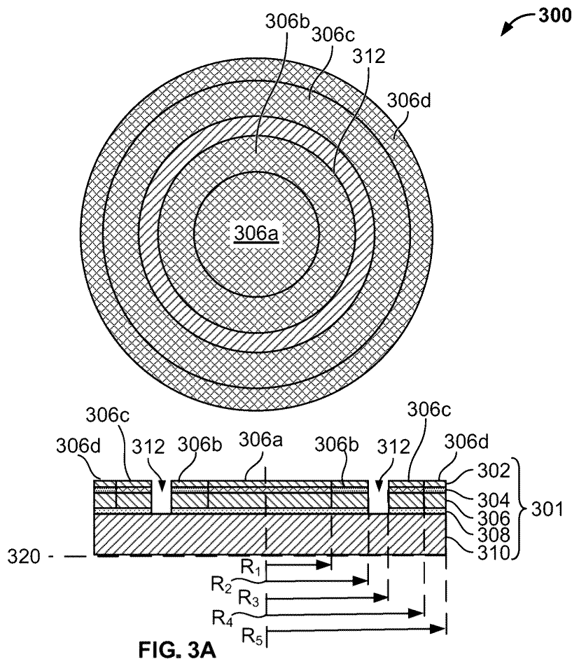

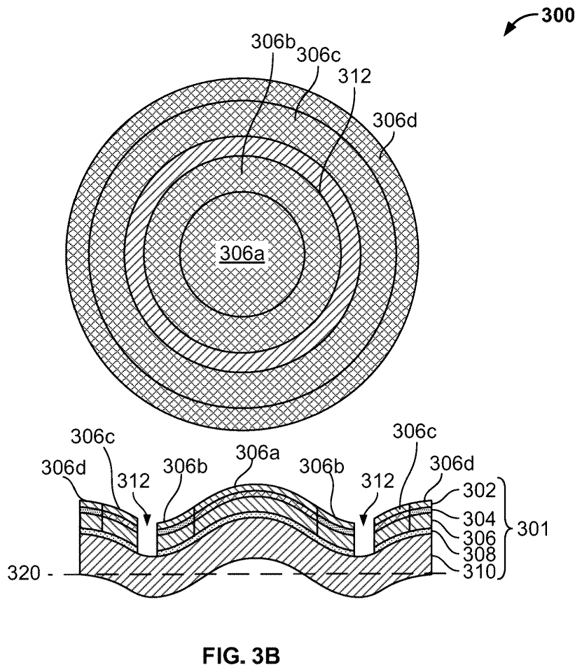

FIG. 3A depicts another exemplary PMUT in accordance with an embodiment of the present disclosure. As with other structures of the present disclosure, the PMUT structure of FIG. 3A and 3B will be depicted and described in simplified format, for example, with the PMUT device 300 having a membrane 301, with the membrane 301 including a piezoelectric layer 306 located between an upper electrode layer 304 and a lower electrode layer 308, an upper structural layer 302 located above the upper electrode layer (e.g., in the direction of transmission/reception), and a lower structural layer 310 located below and providing support for the other layers of the PMUT device. It will be understood that additional layers, intervening layers, bonding layers, and the like may be included within the membrane 301 layers in different embodiments. Further, although particular PMUT designs are depicted and described herein with respect to each of the figures, it will be understood that the PMUT optimization techniques utilized herein are equally applicable to other PMUT designs, including squares, rectangles, ovals, polygon, and irregular shapes, along with varieties of shapes and patterns of removed regions.

The membrane 301 includes inactive portions that include all layers but are inactive, in that these portions do not actively participate in the generating or receiving acoustic signals to directly create or respond to electrical signals. These portions with inactive layers thus also contribute to the static deflection based on layer placement and target residual stresses in the same manner as active non-removed portions. Although inactive layers can be located in any suitable regions of the membrane 301, in an embodiment a central portion of membrane 301 including regions 306a and 306b may include one active region (e.g., 306a) and one inactive region (e.g., 306b) and a surrounding portion of membrane 301 including regions 306c and 306d may include one active region (e.g., 306c) and one inactive region (e.g., 306d). The membrane 301 includes a removed region 312 between regions 306b and 306c, that in the embodiment of FIG. 3A is an annular ring within the circular PMUT 300 structure, although in other embodiments a shape may be rectangular, square, triangular, hexagonal, irregular shaped, other shapes, and combinations thereof. In the embodiment depicted in FIG. 3A and in embodiments described herein, the removed region 312 may have all membrane 301 layers except for lower structural layer 310 removed, e.g., upper structural layer 302, upper electrode layer 304, piezoelectric layer 306, and lower electrode layer 308. With these layers removed, the removed region 312 is also inactive, e.g., does not actively participate in the generating or receiving acoustic signals to directly create or respond to electrical signals, although as described herein the removed region participates in determining the static deflection of the PMUT 300 and corresponding vibration modeshape. Although for purposes of illustration figures herein may be depicted and described with a single removed region, it will be understood that multiple removed regions may be included and may have different shapes, sizes, and removed layers in different implementations.

Each of the regions is defined in the circular PMUT 300 structure by one or more radii, for example, such that the active region 306a is defined by the circular region of radius R₁, inactive region 306b is defined by the annular region defined by inner radius R₁ and outer radius R₂, removed region 312 is defined by the annular region defined by inner radius R₂ and outer radius R₃, active region 306c is defined by the annular region defined by inner radius R₃ and outer radius R₄, and inactive region 306d is defined by the annular region defined by inner radius R₄ and outer radius R₅. As is described herein, modifications to the location, shape, area, removed layers, and other characteristics of the removed regions (e.g., removed region 312) changes the static deflection of the membrane 301. For example, without any static deflection, the membrane 301 and each of its layers lies completely flat when viewed from the side or as a cross section. However, in actual implementations there is often a static deflection of the PMUT with respect to an undeflected plane 320. The static deflection is impacted by a number of factors, including the design of the PMUT 300 (e.g., circular in FIG. 3A), locations and size of removed regions (e.g., removed regions 312), and other factors such as residual stresses of one or more of the PMUT layers, and differences between those residual stress based on layer locations. With respect to the non-removed regions, active and inactive regions can be selected in a manner that decouples electrical from mechanical performance, and as such, the selection of such regions can improve electrical performance but does not modify the static deflection and vibration modeshape. When combined with the mechanical performance optimization of the present disclosure based on target residual stress and/or patterning of removed regions, utilizing inactive regions can further improve overall PMUT performance. Systems and methods for designing, selecting, and implementing non-removed active and inactive regions are described in U.S. patent application Ser. No. 18/403,964, filed Jan. 4, 2024, and entitled “PMUT With Partially Inactive Piezoelectric” and U.S. Provisional Patent Application No. 63/530,560, filed Aug. 3, 2023, and entitled “PMUT With Partially Inactive Piezoelectric,” both of which are incorporated by reference herein in their entirety.

FIG. 3B depicts the exemplary PMUT of FIG. 3A with example static deflection in accordance with an embodiment of the present disclosure. The PMUT 300 depicted in FIG. 3B is identical to FIG. 3A, except that in the cross sectional view of FIG. 3B the static deflection of PMUT 300 is depicted with respect to the undeflected plane 320 of the membrane 301. Although a particular static deflection pattern will differ for different PMUT 300 shapes, removed regions, and the like, in the embodiment depicted in FIG. 3B the portions of the membrane 301 corresponding to the removed regions 312 and the non-removed regions 306b, 306c, and 306d generally deflect below the undeflected plane 320, for example, based on the combination of layer stresses and patterning of membrane 301. Additionally, in response to a target residual stress that increases the residual stress within one or more of the layers or portions thereof, the magnitude, curvature, and slope of the particular deflection will be increased. For example, if the residual stress magnitude were to be increased across the entirety of piezoelectric layer 306, the deflection of the non-removed regions 306a-306d above the undeflected plane 320 may increase, and the deflection associated with the non-removed regions 306b, 306c, and 306d, and removed region 312, may also increase further below the undeflected plane 320. As will be described herein, different patterns of static deflection caused by changes in patterning of removed regions and target residual stress in turn result in changes to the vibration modeshape, allowing the vibration modeshape to be effectively “tuned” for improved electromechanical transduction efficiency, improved SNR, and improved linear performance, and allows achievement of a modeshape with desirable characteristics such as maximizing the curvature within piezoelectric active regions of the membrane. For example, the target residual stress and patterning may result in increased curvature of the vibration modeshape in one or more non-patterned regions of the membrane.

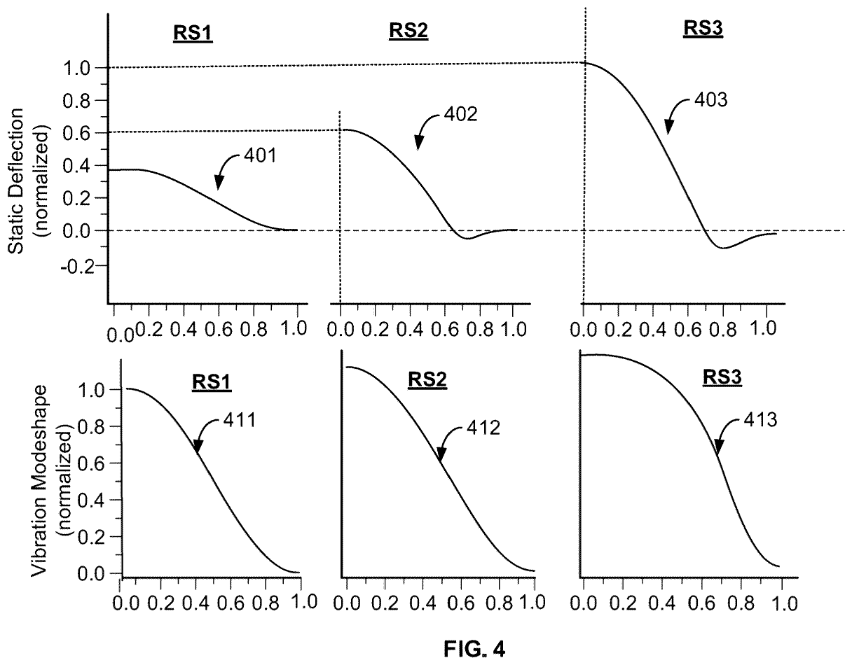

FIG. 4 depicts exemplary plots of static deflection and normalized vibration modeshape for a plurality of residual stress conditions in accordance with an embodiment of the present disclosure. FIG. 4 depicts three residual stress conditions, respectively labeled as RS1, RS2 and RS3, for a common PMUT design and patterning. For example, three different residual stresses are utilized on an identical design of a PMUT as far as shapes, layer types, layer thicknesses, active regions, inactive regions, and patterning of removed regions, with the residual stress magnitude increasing from RS1 to RS2 and RS2 to RS3. The controllable target residual stresses are provided as described herein, for example to one or more layers of the PMUT membrane such as the piezoelectric layer (e.g., achieving the target residual stresses such as via fabrication of components having varied patterning, a test component having adjustable dimensions, simulations, etc.). Each of the residual stress conditions is associated with two plots, both of which include normalized radial distance from center on their abscissa, with the upper plot including normalized static deflection on its ordinate and the lower plot depicting normalized vibration modeshape on its ordinate.

In the embodiment depicted in FIG. 4, the static deflection and vibration modeshape are aligned along the radial axis for each residual stress condition. For example, the static deflection depicted in plot 401 and the vibration modeshape depicted in plot 411 are associated with residual stress condition RS1, the static deflection depicted in plot 402 and the vibration modeshape depicted in plot 412 are associated with residual stress condition RS2, and the static deflection depicted in plot 403 and the vibration waveform depicted in plot 413 are associated with residual stress condition RS3. It will be understood that the particular static deflection and vibration modeshape plots depicted in FIG. 4 are based on an exemplary design, e.g., as depicted in FIGS. 2A, 2B, 3A, and 3B, with a circular PMUT shape and a removed portion in an annular ring within the circular PMUT shape. It will be understood that similar plots and values can be determined from any suitable design, utilizing a common design and different target residual stresses. Different designs will have different patterns of static deflection and vibration modeshape. For example, a circular PMUT with one non-removed region (e.g., compared to two as depicted in FIG. 4) would be unlikely to have both positive and negative normalized static deflections as in conditions RS2 and RS3 of the embodiments depicted in FIG. 4.

Although not clearly visible in plot 401, a partially negative static deflection associated with a removed region is visible having a minimum value centered at a normalized radial distance from center of approximately 0.7 in plots 402 and 403, corresponding to higher residual stress conditions RS2 and RS3. In the embodiment depicted in FIG. 4, the vibration modeshapes magnitude is largest at the PMUT center and gradually approaching zero near the edge, with the normalized vibration modeshape having an increased value over a larger central region of the PMUT membrane with increasing residual stress magnitude. In the embodiment of FIG. 4, the static deflection associated with RS2 and depicted by plot 402 exhibits substantial differences compared to the static deflection associated with RS1 and depicted by plot 401, such as a maximally negative static deflection centered at a normalized radial distance of approximately 0.7 for RS2 compared to a positive static deflection at the same normalized radial distance for RS1. Nonetheless, based on the residual stress conditions RS1 and RS2, the resulting vibration modeshapes 411 and 412 are relatively similar, although the vibration modeshape 412 associated with RS2 does have differences in curvature compared to RS1 which, combined with differences in the static deflection, affect the resulting device performance including transmission and reception characteristics, such as improving electromechanical transduction efficiency, reducing non-linearity during vibration, or increasing SNR.

The increase in magnitude of the stress in the RS3 case results in additional changes to both the static deflection and the vibration modeshape. With respect to the static deflection, as depicted by plot 403 for RS3, a larger portion of the PMUT membrane has a negative static deflection between approximately 0.65 to 1 and has a greater curvature and slope than either plot 401 or 402. The associated vibration modeshape 413 has significant additional area under it and increased curvature in non-patterned and/or active regions. Regions of greater slope and/or curvature (e.g., greater than a threshold slope and/or curvature) may correspond, for example, to regions that may be active in certain PMUT designs. As another example, regions with a relatively low or minimum slope and/or curvature may be associated with inactive regions. Compared to the vibration modeshapes 411 and 412, the vibration modeshape 413 may have improved electromechanical transduction efficiency, higher SNR, and an increased mechanical linearity.

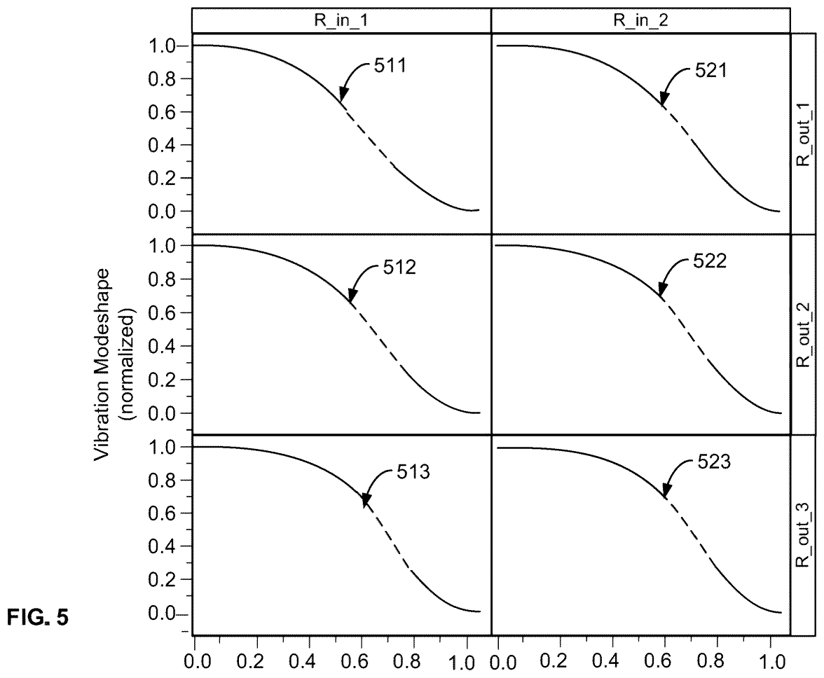

FIG. 5 depicts exemplary plots of normalized vibration modeshape for a plurality of patterning radii in accordance with an embodiment of the present disclosure. As described herein, patterning including removal of portions of layers according to a predetermined pattern may be performed in a variety of different manners. FIG. 5 depicts examples of how modification of this patterning, such as the location and width of the patterning, can affect the vibration modeshape for an otherwise common design (e.g., having an identical PMUT shape and target residual stress). It will be understood that similar analysis can be performed for other PMUT shapes, residual stresses, and patterning, such as via fabrication of components having varied patterning, a test component having adjustable dimensions, simulations, etc.

In the embodiment of FIG. 5, patterning is depicted for a removed annular ring of a circular PMUT having an inner radius R_in and an outer radius R_out (e.g., corresponding to rin and rout in FIGS. 2A and 2B and R₂ and R₃ in FIGS. 3A and 3B), with two options R_in_1 (e.g., at approximately 0.55 normalized radial distance from center) and R_in_2 (e.g., at approximately 0.6 normalized radial distance from center) for R_in. Similarly, three options are depicted for R_out, including R_out_1 (e.g., at approximately 0.7 normalized radial distance from center), R_out_2 (e.g., at approximately 0.75 normalized radial distance from center), and R_out_3 (e.g., at approximately 0.8 normalized radial distance from center). Accordingly, six plots are depicted with the patterned portion between R_in and R_out depicted with dashed lines, with vibration modeshape 511 corresponding to R_in_1 and R_out_1, vibration modeshape 512 corresponding to R_in_1 and R_out_2, vibration modeshape 513 corresponding to R_in_1 and R_out_3, vibration modeshape 521 corresponding to R_in_2 and R_out_1, vibration modeshape 522 corresponding to R_in_2 and R_out_2, and vibration modeshape 523 corresponding to R_in_2 and R_out_3.

As can be seen from the respective vibration modeshapes depicted in FIG. 5, changes to just the location and radial width of the patterning modify the vibration modeshape as a whole for each PMUT design, for example, resulting in increased curvature in non-patterned and/or active regions. For example, in a comparison between vibration modeshape 511 and 522, modeshape 511 begins decreasing earlier and at a greater rate than modeshape 522, and the outermost portion of modeshape 511 has lower curvature than modeshape 522. Differences of a similar type and scale are apparent between each of the modeshapes. This information can be combined with other design characteristics, such as the magnitude of the respective static deflections, active and inactive regions, end use application, and the like, to select a pattern that optimizes transmission and reception characteristics such as improved electromechanical transduction efficiency, higher SNR, mechanical linearity, etc.

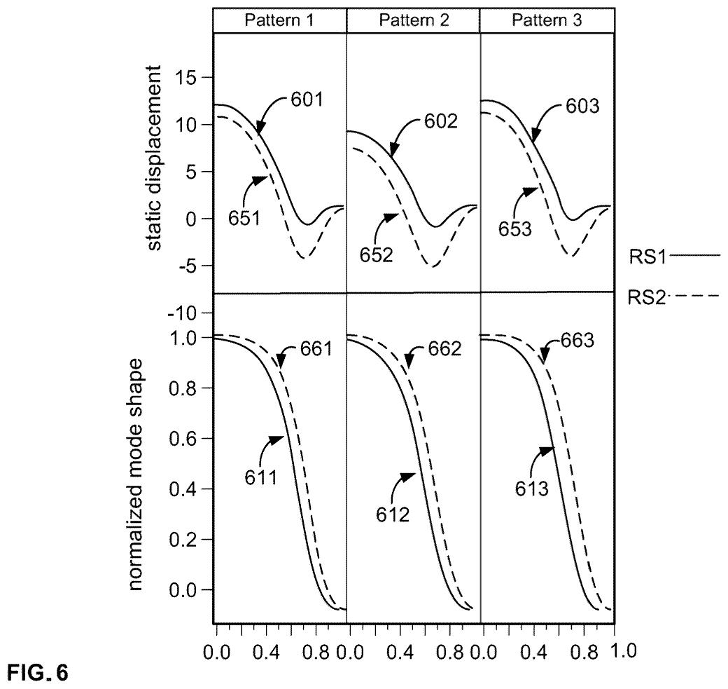

FIG. 6 depicts exemplary plots of static deflection and normalized vibration modeshape for a plurality of patterns and residual stress conditions in accordance with an embodiment of the present disclosure. As described for FIGS. 4-5, the target residual stress and the PMUT patterning can be modified in a controllable manner to modify static deflection and vibration modeshape, for example, as determined by use of simulations, prototype components, a test structure with modifiable parameters, and combinations thereof. In FIG. 6, different static deflections and vibration modeshapes are depicted for combinations of three different patterns of removed portions of the PMUT and two different target residual stresses to one or more layers of the PMUT. The plots depicted in FIG. 6 correspond to a circular PMUT with a removed region in an annular ring pattern, although it will be understood that similar analysis can be performed for other PMUT shapes, residual stresses, and patterning, such as via fabrication of components having varied patterning, a test component having adjustable dimensions, simulations, etc.

FIG. 6 depicts twelve total plots within six regions. The abscissae for the regions are depicted along the lower axis of the bottom three regions, in units of normalized radial distance from the PMUT center, i.e., with 0.0 corresponding to the membrane center and 1.0 (depicted as the next 0.0 value in some instances) corresponding to the external boundary of the membrane. The lower three regions depict six plots of vibration modeshapes over this normalized radial distance, and are in units of normalized vibration modeshape. The upper three regions depict six plots of static deflection over this normalized radial distance, and are in units of micrometers relative to a zero or undeflected plane.

The plots in FIG. 6 depict static deflection and vibration modeshape for each of six combinations of PMUT patterning and target residual stress, with each of three patterns Pattern 1, Pattern 2, and Pattern 3 depicted in two vertically aligned regions and each of the target residual stresses RS1 and RS2 (e.g., corresponding to a higher target residual stress magnitude than RS1) depicted as solid lines (for RS1) and dashed lines (for RS2) in each region, respectively. Accordingly, for Pattern 1 and RS1 static deflection is depicted as plot 601 while normalized vibration modeshape is depicted as plot 611, for Pattern 2 and RS1 static deflection is depicted as plot 602 while normalized vibration modeshape is depicted as plot 612, for Pattern 3 and RS1 static deflection is depicted as plot 603 while normalized vibration modeshape is depicted as plot 613, for Pattern 1 and RS2 static deflection is depicted as plot 651 while normalized vibration modeshape is depicted as plot 661, for Pattern 2 and RS2 static deflection is depicted as plot 652 while normalized vibration modeshape is depicted as plot 662, and for Pattern 3 and RS2 static deflection is depicted as plot 653 while normalized vibration modeshape is depicted as plot 663.

As can be seen from the respective static deflections and associated vibration modeshapes depicted in FIG. 6, the combined effects of changes to PMUT patterning and residual stress can have a substantial effect on both the static deflection and the vibration modeshape of the respective PMUTs. For example, the peak-to-peak static deflection increases with the greater magnitude target residual stress, and also results in more area under the curve of the vibration modeshape. In this manner, an increase in peak-to-peak static deflection results in an increase in PMUT performance. Different patterning similarly impacts both the static deflection and the overall shape of the vibration modeshape, for example, resulting in increased curvature in non-patterned and/or active regions. In this manner, a combination patterning and target residual stress can be selected to improve electromechanical transduction efficiency, increase SNR, and improve linearity, and to achieve other desired characteristics such as energy efficiency, frequency, and bandwidth.

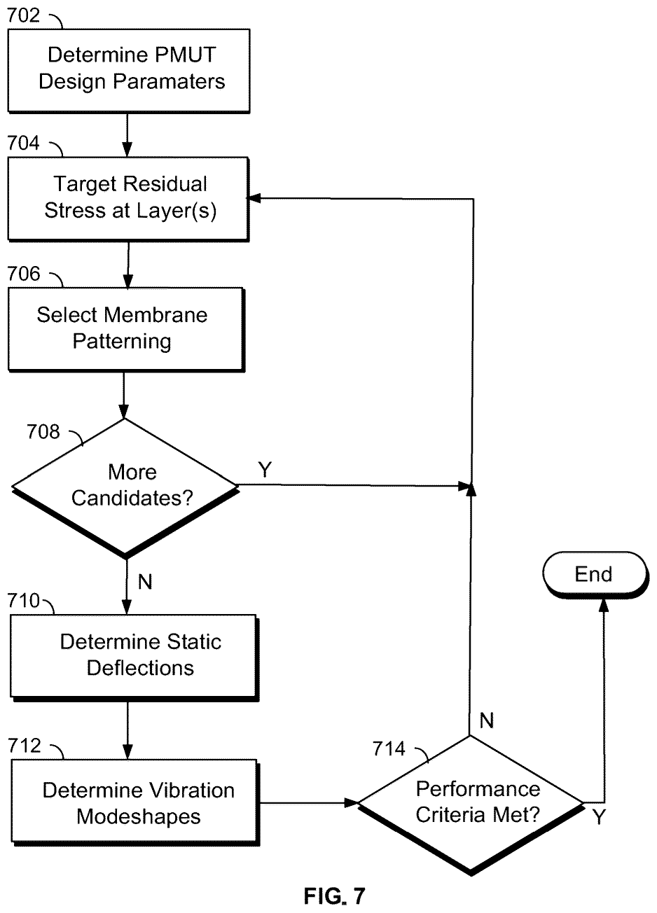

FIG. 7 depicts exemplary steps of selecting residual stresses and patterning a PMUT in accordance with an embodiment of the present disclosure. Although particular steps are depicted in a certain order for FIG. 7, steps may be removed, modified, or substituted, and additional steps may be added in certain embodiments, and in some embodiments, the order of certain steps may be modified.

Processing starts at step 702, where initial PMUT design parameters are determined. PMUT design parameters are determined based on a variety of factors such as the end use application, size limitations, cost limitations, material selection and availability, sensitivity requirements, power usage requirements, fabrication techniques, bandwidth, operating frequency, transmit sensitivity, receive sensitivity, electromechanical transduction efficiency requirements, SNR requirements and the like. These parameters include the PMUT shape, size, layers, layer thicknesses, general fabrication processes (e.g., material deposition and removal), and potential location for PMUT patterning and material removal. Once the initial design parameters have been determined, processing may continue to step 704.

At step 704, a target residual stress condition is provided based on the PMUT design from step 702. As described herein, the residual stress within one or more layers may be controlled based on the manner in which layers are deposited and/or bonded, or by additional processing steps such as applied temperature and pressure conditions. The application of the residual stress may be done on physical parts such as prototype parts, on customized test components that are modifiable, in simulations, or other suitable methods. As described herein, this process of applying residual stress conditions to the PMUT design may be repeated for multiple target residual stresses via the loops initiated at step 708 or 714. Once a residual stress is provided, processing may continue to step 706.

At step 706, a particular patterning is applied to the PMUT design from step 702. As described herein, patterning includes removal of one or more of the layers of the PMUT membrane at predetermined locations within the PMUT. The location of material removal is customized to each design, but in many embodiments, is in some sort of uniform pattern such as one or more concentric shapes corresponding to the overall shape of the PMUT (e.g., one or more annular rings for a circular PMUT). The patterning is modified at different iterations of step 706, for example, changing the location, size, and removed layers in different iterations. This patterning may be performed on physical parts such as prototype parts, on customized test components that are modifiable, in simulations, or by other suitable methods. As described herein, this process of patterning the PMUT design may be repeated for multiple patterns via the loops initiated at step 708 or 714. Once the PMUT is patterned, processing may continue to step 708.

At step 708, it is determined whether more candidates are desired for testing and/or simulation. At different stages of the design process, differing numbers and varieties of candidate PMUT configurations may be needed. For example, at an early stage of a PMUT design process, a selection of highly differentiated patterning and target residual stresses may be selected for testing, for example, to determine high-level performance characteristics such as energy efficiency, bandwidth, operating frequency, transmit sensitivity, receive sensitivity, electromechanical transduction efficiency, SNR, and the like. At later stages of design, a selection of less differentiated patterning and target residual stress may be selected to tune to particular performance criteria, such as electromechanical transduction efficiency, SNR, and linearity. If more candidate designs are needed, processing of the loop of steps 704, 706, and 708 repeats. If an adequate set of candidate designs has been generated, processing continues to step 710.

At step 710, static deflections are determined for each of the candidates, for example, based on physical testing and/or simulations. Processing then continues to step 712, where vibration modeshapes are determined for each of the candidates. Processing then continues to step 714.

At step 714, it is determined whether the performance criteria are met for any of the candidate designs, such as via physical testing and/or simulations. In some embodiments, whether the performance criteria are met is determined directly from the static deflection and/or vibration modeshape, based on known associations of one or both of the static deflection and vibration modeshape to particular design criteria. In some embodiments, the design criteria may be the static deflection and/or vibration modeshape itself, for example, by comparing these to a reference static deflection or vibration modeshape. In some embodiments, and in combination with analysis of the static deflection and/or vibration modeshape, performance criteria such as energy efficiency, bandwidth, operating frequency, transmit sensitivity, receive sensitivity, electromechanical transduction efficiency, SNR, linearity, and the like may be measured. If these results demonstrate that the performance criteria are met, or that patterning and target residual stress meeting the performance criteria can be interpolated or otherwise determined from the results, the processing of FIG. 7 ends. If additional candidates are needed to meet the performance criteria, processing returns to step 704.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A piezoelectric micromachined ultrasonic transducer (PMUT), comprising:
a membrane comprising a plurality of layers including at least a first electrode layer, a second electrode layer, and a piezoelectric layer located between the first electrode layer and the second electrode layer, wherein a first layer of the plurality of layers has a target residual stress; and
a pattern on the membrane including removed portions of one or more of the plurality of layers, wherein a predetermined static deflection of the membrane is determined by the target residual stress of the first layer and the patterning of the membrane.

2. The PMUT of claim 1, further comprising a predetermined vibration modeshape of the membrane, wherein the predetermined vibration modeshape is determined by the predetermined static deflection.

3. The PMUT of claim 2, wherein the predetermined vibration modeshape corresponds to a higher electromechanical transduction efficiency within one or more active regions of the membrane.

4. The PMUT of claim 2, wherein the predetermined vibration modeshape corresponds to a higher transmit and receive sensitivity.

5. The PMUT of claim 2, wherein the predetermined vibration modeshape corresponds to a substantially linear motion during PMUT vibration.

6. The PMUT of claim 2, wherein the predetermined vibration modeshape has increased curvature in one or more non-patterned regions of the membrane.

7. The PMUT of claim 1, wherein the first layer comprises the piezoelectric layer.

8. The PMUT of claim 7, wherein the target residual stress comprises a first target residual stress, further comprising a second layer of the plurality of layers having a second target residual stress, wherein the predetermined static deflection of the membrane is additionally determined by the second target residual stress.

9. The PMUT of claim 7, wherein the target residual stress comprises a first target residual stress, further comprising each of at least two more of the plurality of layers having a respective target residual stress, wherein the predetermined static deflection of the membrane is additionally determined by the respective target residual stresses.

10. The PMUT of claim 1, wherein the membrane comprises a circular membrane and wherein the pattern of the membrane comprises an annular ring within the circular membrane.

11. The PMUT of claim 10, wherein the annular ring has an inner radius and an outer radius, and wherein the inner radius and the outer radius are selected based on the target residual stress to determine the predetermined the static deflection.

12. The PMUT of claim 1, wherein a maximum or minimum static deflection of the predetermined static deflection is located within the removed portions.

13. The PMUT of claim 12, wherein the maximum or minimum static deflection is respectively above or below an undeflected plane of the membrane.

14. The PMUT of claim 1, wherein the pattern comprises multiple non-contiguous removed portions.

15. The PMUT of claim 1, wherein a shape of the membrane comprises one of a rectangular shape, a square shape, a hexagonal shape, or a triangular shape.

16. The PMUT of claim 1, wherein a shape of the membrane comprises an irregular shape.

17. The PMUT of claim 1, wherein a vibration modeshape of the PMUT is based on the predetermined static deflection, and wherein an active portion of the piezoelectric layer is defined in accordance with the vibration modeshape.

18. The PMUT of claim 17, wherein the active portion is based on a curvature of portions of the vibration modeshape.

19. The PMUT of claim 1, wherein the removed portions of one or more of the plurality of layers includes a portion of the first layer having the target residual stress.

20. A piezoelectric micromachined ultrasonic transducer (PMUT), comprising:
a membrane comprising a plurality of layers including at least a first electrode layer, a second electrode layer, and a piezoelectric layer located between the first electrode layer and the second electrode layer, wherein a first layer of the plurality of layers has a target residual stress; and
a pattern on the membrane including removed portions of one or more of the plurality of layers, wherein a predetermined vibration modeshape of the membrane is determined by the target residual stress of the first layer and the patterning of the membrane.

21. A method for designing a piezoelectric micromachined ultrasonic transducer (PMUT), comprising:
determining an initial PMUT design, including a shape of a membrane and a plurality of layers of the membrane, wherein the plurality of layers comprise at least a first electrode layer, a second electrode layer, and a piezoelectric layer located between the first electrode layer and the second electrode layer;
selecting a plurality of target residual stresses to a first layer of the plurality of layers;
applying a plurality of patternings to the membrane, wherein each patterning comprises a removal of portions of one or more of the plurality of layers;
determining a static deflection associated with each combination of the target residual stresses and applied patternings; and
selecting one of the target residual stresses and one of the applied patternings based on the determined static deflections or a plurality of vibration modeshapes that are each based on a respective one of the determined static deflections.
